(19) United States
(12) Patent Application Publication
(10) Pub. No.: US 2011/0291203 A1
(43) Pub. Date: Dec. 1, 2011

(54) SEMICONDUCTOR DEVICE AND METHOD FOR MANUFACTURING THE SAME

(75) Inventor: Akio MIYAO, Kanagawa-ken (JP)

(73) Assignee: Kabushiki Kaisha Toshiba, Tokyo (JP)

(21) Appl. No.: 13/022,882

(22) Filed: Feb. 8, 2011

(30) Foreign Application Priority Data
May 31, 2010 (JP) 2010-124295

(51) Int. Cl. H01L 29/772; H01L 21/28

(52) U.S. Cl. 257/409; 438/586; 257/E29.242; 257/E21.158; 257/488

(57) ABSTRACT

A semiconductor device according to an embodiment of the present invention includes a active region, a drain electrode, a source electrode, a gate electrode, a passivation layer, a source field plate, and a electrical connection. The active region is formed on a semiconductor substrate. The drain electrode, the source electrode, and the gate electrode are formed on a surface of the active region to be separated from each other. The passivation layer is formed on a surface of the active region between the drain electrode and the source electrode to cover the gate electrode. The source field plate is formed at least at a position including an upper portion of the drain-side end portion of the gate electrode on a surface of the passivation layer. The electrical connection is formed on the passivation layer to connect the source field plate and the source electrode. The electrical connection has a width of the electrical connection smaller than electrode widths of the source field plate and the source electrode.

### CROSS REFERENCE TO RELATED APPLICATIONS

This application is based upon and claims the benefit of priority from the prior Japanese Patent Application No. 2010-124295 filed in Japan on May 31, 2010; the entire contents of which are incorporated herein by reference.

### FIELD

Embodiments described herein relate generally to a semiconductor device having a field plate and a method for manufacturing the same.

### BACKGROUND

In a semiconductor device such as a transistor having a conventional field plate, a drain electrode, a gate electrode, and a source electrode are formed on a semiconductor substrate, and, furthermore, a source field plate is formed between the drain electrode and the source electrode over a passivation layer with appropriate thickness. The source field plate is extended to a drain electrode side over the gate electrode through the passivation layer. Herein, a drain side end of the source field plate exists between the gate electrode and the drain electrode. The source field plate is electrically connected to a source electrode. The connection width is substantially equal to a width of electrodes (a length in a direction perpendicular to a direction of a current flow) of the source electrode and the source field plate.

By reducing the electric field concentration of the drain side edge of the gate electrode, the source field plate enables to improve break down voltages. Therefore, a higher output power is available with a semiconductor device having a source field plate.

In such a conventional semiconductor device as a transistor having the source field plate, wide electrodes are formed on a gate electrode through a passivation layer. Since the electrode is formed in contact with the passivation layer, a capacitance is generated between the gate electrode and the source field plate. Therefore, a gate parasitic capacitance Cgs between the gate electrode and the source electrode increases. When the gate parasitic capacitance Cgs increases as described above, the characteristics of the semiconductor device, for example, a gain of the semiconductor device is deteriorated.

### BRIEF DESCRIPTION OF THE DRAWINGS

FIG. 1 is a top view showing a semiconductor device according to a first embodiment of the present invention.

FIG. 2 is a sectional view of the semiconductor device along a dotted chain line A—A′ in FIG. 1.

FIG. 3 is a diagram for explaining a method for manufacturing the semiconductor device according to the first embodiment of the present invention, and is a top view of a device to explain the step of forming a passivation layer.

FIG. 4 is a sectional view of the device along a dotted chain line A-A′ in FIG. 3.

FIG. 5 is a diagram for explaining a method for manufacturing a semiconductor device according to the first embodiment of the present invention, wherein a top view of a device is shown to explain the step of forming a first photo resist layer.

FIG. 6 is a sectional view of the device along a dotted chain line A-A′ in FIG. 5.

FIG. 7 is a diagram for explaining a method for manufacturing a semiconductor device according to the first embodiment of the present invention, wherein a top view of a device is shown to explain the step of depositing a metal.

FIG. 8 is a sectional view of the device along the dotted chain line A-A′ in FIG. 7.

FIG. 9 is a top view showing a semiconductor device according to a second embodiment of the present invention.

FIG. 10 is a sectional view of the semiconductor device along the dotted chain line A-A′ in FIG. 9.

FIG. 11 is a diagram showing a method for manufacturing a semiconductor device according to the second embodiment of the present invention, wherein a top view of a device is shown to explain the step of forming first and second photo resist layers.

FIG. 12 is a sectional view of the device along the dotted chain line A-A′ in FIG. 11.

FIG. 13 is a diagram for explaining a method for manufacturing a semiconductor device according to the second embodiment of the present invention, wherein a top view of a device is shown to explain the step of depositing a metal.

FIG. 14 is a sectional view of the device along a dotted chain line A-A′ in FIG. 13.

FIG. 15 is a top view showing a semiconductor device according to a third embodiment of the present invention.

FIG. 16 is a sectional view of the semiconductor device along a dotted chain line A-A′ in FIG. 15.

FIG. 17 is a diagram to explain a method for manufacturing a semiconductor device according to the third embodiment of the present invention, wherein a top view of a device is shown to explain the step of forming first and second photo resist layers and a peripheral portion thereof.

FIG. 18 is a sectional view of the device along the dotted chain line A-A′ in FIG. 17 and a peripheral portion thereof.

### DETAILED DESCRIPTION

A semiconductor device according to an embodiment of the present invention includes a active region, a drain electrode, a source electrode, a gate electrode, a passivation layer and a source field plate. The active region is formed on a semiconductor substrate. The drain electrode and the source electrode are formed on a surface of the active region with a space. The gate electrode is formed between the drain electrode and the source electrode. The passivation layer is formed on a surface of the active region. The source field plate is formed on the passivation layer. The drain side of the source field plate is extended over the gate electrode to drain side. Here, the drain side end of the source field plate exists between the gate electrode and the drain electrode. The electrical connection is formed on the passivation layer to connect the source field plate and the source electrode. The connection has same width as the source field plate and the source electrode.

A method for manufacturing a semiconductor device according to an embodiment of the present invention includes the steps of forming a drain electrode, a source electrode, and a gate electrode on a surface of a active region formed on a semiconductor substrate, forming a passivation layer, forming a first photo resist layer, and forming a source field plate and a electrical connection. In the step of forming a passivation layer, a passivation layer is formed on the active region to cover the gate electrode. In the step of forming a first photo resist layer, a first photo resist layer is formed on the passivation layer having electrode with openings formed at least over an upper portion of a drain-side end portion of the gate electrode and over the source electrode and a electrical connection with openings formed between the electrode to connect the openings and having an opening width smaller than that of the electrode. In the step of forming a source field plate and a electrical connection, the first photo resist layer is removed to form a source field plate and a electrical connection electrically connecting the source field plate and the source electrode and having a electrical connection width smaller than electrode widths of the electrodes after a metal is deposited by using the first photo resist layer as a mask.

The semiconductor device and a method for manufacturing a semiconductor device will be described below with reference to the accompanying drawings.

### First Embodiment

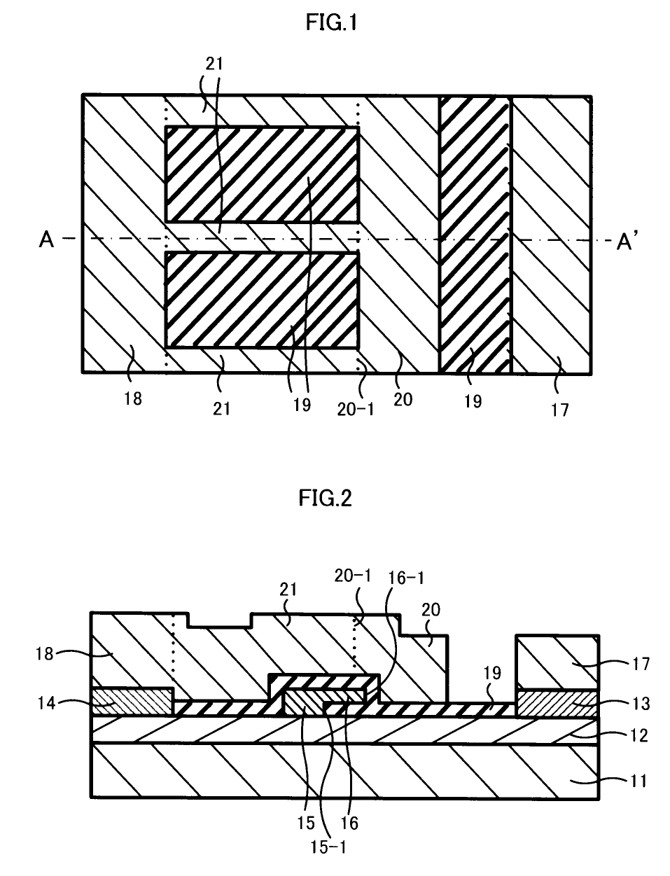

FIG. 1 is a top view showing a semiconductor device according to the first embodiment. FIG. 2 is a sectional view of a semiconductor device along a dotted chain line A-A′ in FIG. 2. As shown in FIG. 2, an active region 12 is formed on a semiconductor substrate 11. The semiconductor substrate 11 consists of GaAs which is a material having in a good high-frequency characteristic. The active region 12 consists of n-type AlGaAs. The active region 12 is a layer functioning as a channel of the semiconductor device.

On the active region 12, a drain electrode 13 and a source electrode 14 are formed with a space between them. On the active region 12 between the drain electrode 13 and the source electrode 14, a gate electrode 15 is formed. The drain electrode 13 and the source electrode 14 consist of a material which is in ohmic contact with, for example, the active region 12, and the gate electrode 15 consists of a material forming a Schottky-barrier-junction, for example, with the active region 12.

On the active region 12, a gate field plate 16 is formed through a passivation layer 19, which will be described later. The gate field plate 16 is connected to a drain-side end portion of the gate electrode 15. The gate field plate 16 consists of the same material as that of the gate electrode 15.

The gate field plate 16 enables to prevent the electric field concentration at the drain-side end portion of the gate electrode 15 and thereby improving a break down voltage of the semiconductor device. Therefore, although the semiconductor device according to the embodiment preferably has the gate field plate 16, the gate field plate 16 is not always necessary.

On a surface of the drain electrode 13, a drain connect electrode 17 is formed. On a surface of the source electrode 14, a source connect electrode 18 is formed. The connect electrodes 17 and 18 consist of a material such as gold.

The passivation layer 19 is formed on the active region 12 between the drain electrode 13 and the source electrode 14 to cover the gate electrode 15 and the gate field plate 16. The passivation layer 19 consists of, for example, SiN. However, the passivation layer 19 may consist of SiO2 or the like.

A source field plate 20 is formed on the passivation layer 19 between the source electrode 14 and the drain electrode 13 so as to cover the gate electrode 15. The source field plate 20 consists of a material such as gold.

The source field plate 20 is formed such that at least a source-side end portion 20-1 of the electrode 20 is located at a position closer to the source electrode than the drain-side end portion 16-1 of gate field plate 16. More specifically, the source field plate 20 is formed at a position covering the drain-side end portion of the gate field plate 16. When the source field plate 20 is formed at the position, the drain-side end portion of the gate field plate 16 is prevented from the electric field concentration. Therefore, the breakdown voltage of the semiconductor device is improved.

When the gate field plate 16 is not formed, the source field plate 20 is formed such that at least the source-side end portion 20-1 of the electrode 20 is located at a position closer to the source electrode than the drain-side end portion 15-1 of the gate electrode 15. Accordingly, the drain-side end portion 15-1 of the gate electrode 15 is prevented from being a high potential due to concentration of an electric field, and thus the break down voltage of the semiconductor device is improved.

The source field plate 20 and the source connect electrode 18 are connected to each other by a plurality of parallel linear thin electrical connections 21, as shown in FIG. 1. The electrical connections 21 is formed on the passivation layer 19 between the source connect electrode 18 and the source field plate 20 which are arranged to face each other such that the electrical connection 21 is in contact with the passivation layer 19. Each of the electrical connections 21 has a electrical connection width smaller than the electrode widths of the source connect electrode 18 and the source field plate 20. As shown in FIGS. 1 and 2, when the source connect electrode 18 and the source electrode 14 have the same sizes, the electrical connection width of each of the electrical connections 21 is smaller than the electrode width of the source electrode 14. Each of the electrical connections 21 consists of the same material (for example, gold) as those of the source field plate 20 and the source connect electrode 18 and are formed to be integral with the source field plate 20 and the source connect electrode 18. The electrical connections 21 are preferably formed at intervals of 50 μm or less. The reason will be described later.

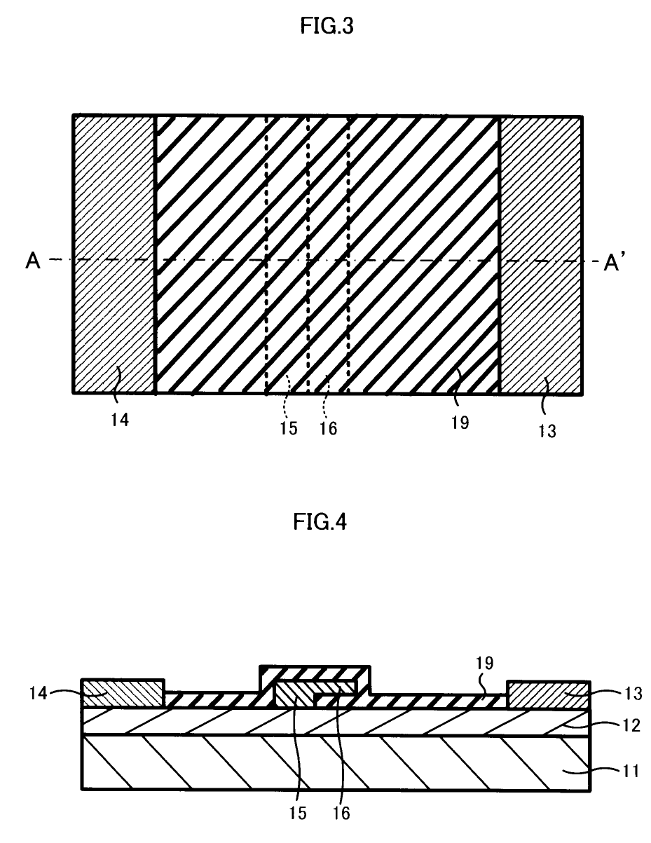

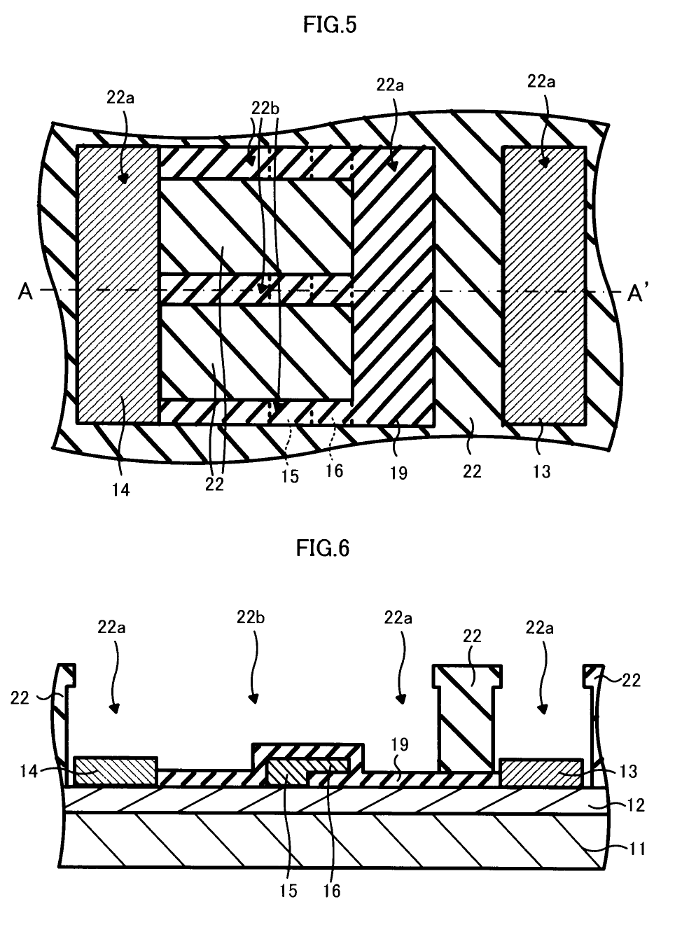

The method for manufacturing a semiconductor device stated above will be described below with reference to FIGS. 3 to 8. FIGS. 3, 5 and 7 are top views of the device to explain the method for manufacturing a semiconductor device, and FIGS. 4, 6, and 8 are sectional views of the device along a dotted chain line A-A′ in FIGS. 3, 5, and 7, respectively. In FIGS. 5 and 6, the device is magnified to a peripheral portion of the device and shown for descriptive convenience.

As shown in FIGS. 3 and 4, the active region 12 is formed on a surface of the semiconductor substrate 11. Then, the drain electrode 13, the source electrode 14, the gate electrode 15 and the gate field plate 16 are formed on the active region 12. Thereafter, the passivation layer 19 consisting of SiN, for example, is formed to cover the gate electrode 15 and the gate field plate 16 on the active region 12 between the drain electrode 13 and the source electrode 14. The active region 12 is formed by epitaxial growth, for example. The electrodes 13 to 16 are formed by a lift-off method, for example. The passivation layer 19 is formed by a plasma CVD method, for example. In the step of forming the gate electrode 15 and the gate field plate 16 on the active region 12, the passivation layer 19 is formed on the active region 12 first. Although not shown, a line and space is formed for forming the gate electrode 15. A resist layer having the line and space for forming the gate electrode 15 and the gate field plate 16 is formed on the entire surface. Then, the gate electrode 15 and the gate field plate 16 are formed by using the resist layer as a mask. After the resist layer is removed, the active region 12 is covered with the passivation layer 19.

As shown in FIGS. 5 and 6, a first photo resist layer 22 is formed on the passivation layer 19. The first photo resist layer 22 has an electrode forming opening 22a for forming the drain connect electrode 17, the source connect electrode 18 and the source field plate 20 shown in FIGS. 1 and 2. The first photo resist layer 22 further has a electrical connection forming opening 22b for forming a plurality of electrical connections 21. Each of the openings 22a and 22b is formed in an overhung shape.

The electrode forming openings 22a are formed at least above the drain-side end portion of the gate field plate 16, the drain electrode 13, and the source electrode 14, respectively. The plurality of electrical connection forming openings 22b are formed between the electrode forming openings 22a, 22a over the source electrode 14 and the gate field plate 16 to connect the openings 22a, 22a to each other. A width of the each opening of the electrical connection forming openings 22b is smaller than the width of the each opening of the electrode forming opening 22a. The width of the opening means a length of an opening in the same direction as those of the electrode width and the electrical connection width.

The first photo resist layer 22 is formed in the following manner. For example, a first photo resist material is coated on the entire surface of the device as a photosensitive organic film. Thereafter, a second photo resist material is coated on the entire surface of the first photo resist material having a mask pattern which exposes portions for forming the openings 22a and 22b. The first photo resist material is removed by reactive dry etching or chemical dry etching by using the second photo resist mask pattern. Finally, the second photo resist pattern is removed to form the first photo resist layer 22. In place of the first photo resist layer 22, an SiN film may be formed in the same method as described above. The formation of the opening in this case may be performed by removing unnecessary portions of the SiN film by chemical dry etching.

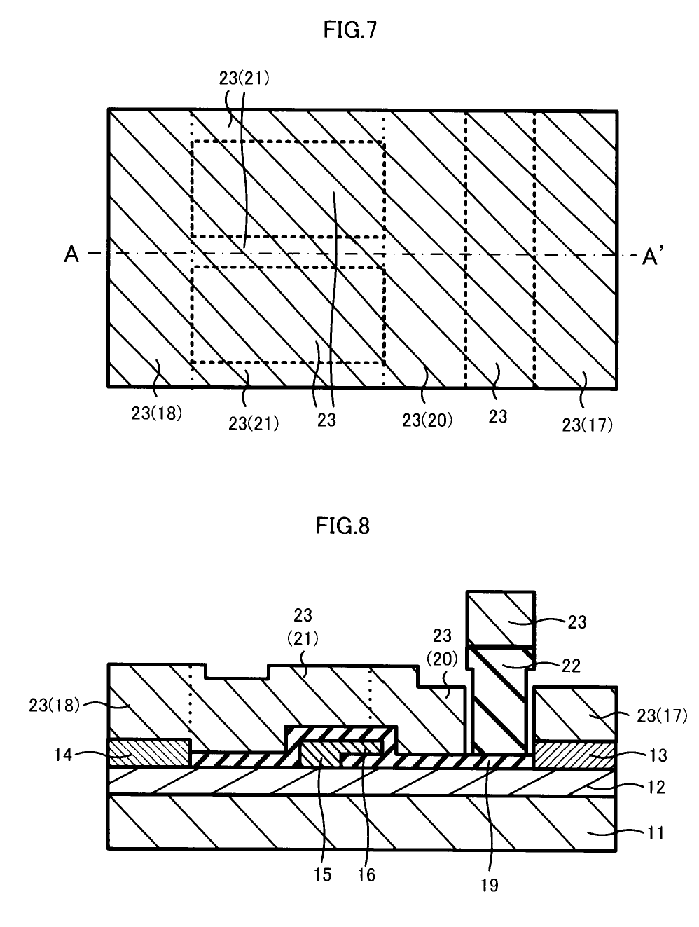

As shown in FIGS. 7 and 8, a metal 23, for example, gold is deposited by using the first photo resist layer 22 as a mask. By the deposition of the metal 23, the drain connect electrode 17, the source connect electrode 18, the source field plate 20 and the plurality of electrical connections 21 are formed at once. By the step, the metal 23 is also deposited on the first photo resist layer 22.

Finally, the first photo resist layer 22 is removed together with the metal 23 on the layer 22. In this manner, the semiconductor device shown in FIGS. 1 and 2 is manufactured.

The semiconductor device according to the embodiment described above, the electrical connection width of each of the electrical connections 21 is smaller than a electrical connection width of a conventional electrical connection. The capacitances between the gate electrode 15 and the plurality of electrical connections 21 are reduced compared with the conventional semiconductor device. Therefore, a gate parasitic capacitance Cgs between the gate electrode 15 and the source electrode 14 can be reduced. In this manner, characteristics such as the gain of amplification of the semiconductor device can be improved.

### Second Embodiment

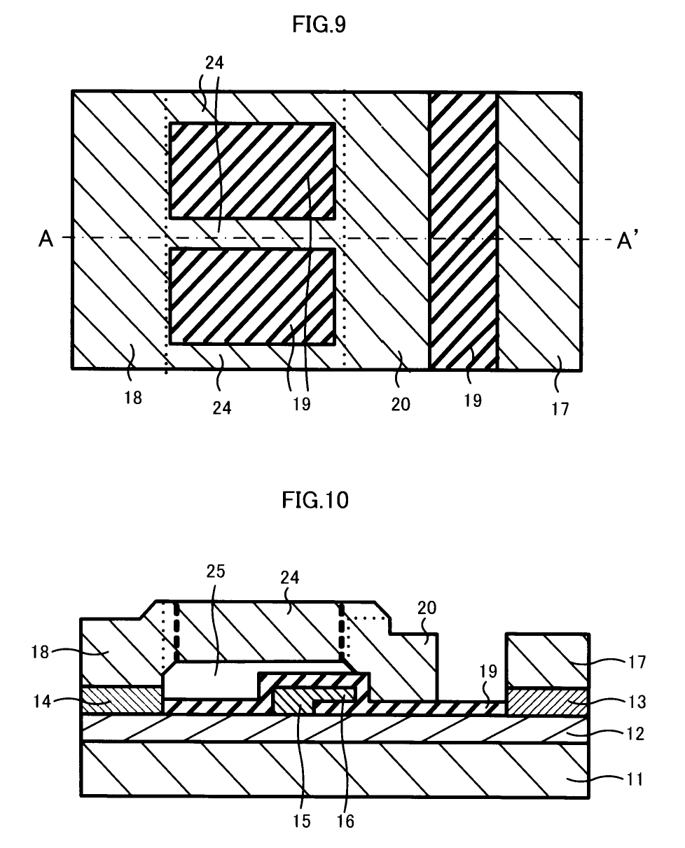

FIG. 9 is a top view showing a semiconductor device according to a second embodiment of the present invention. FIG. 10 is a sectional view of a semiconductor device along a dotted chain line A-A′ in FIG. 9. The semiconductor device shown in FIGS. 9 and 10 is different from the semiconductor device according to the first embodiment in that a plurality of electrical connections 24 are formed at a position spaced apart from the passivation layer 19. More specifically, the semiconductor device according to the second embodiment is different from the semiconductor device according to the first embodiment in that a space 25 is provided between each of the electrical connections 24 and the passivation layer 19.

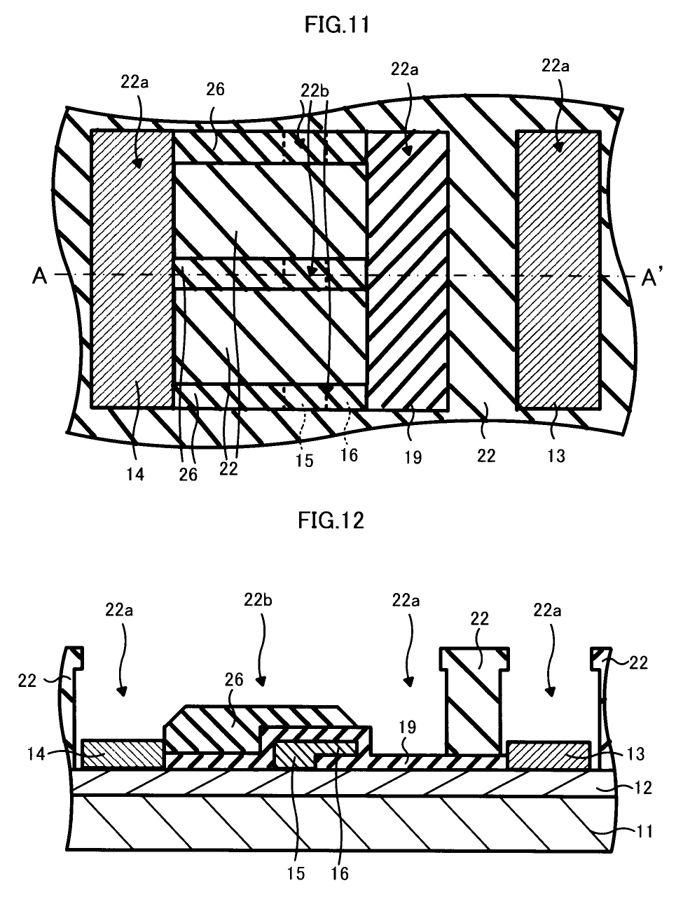

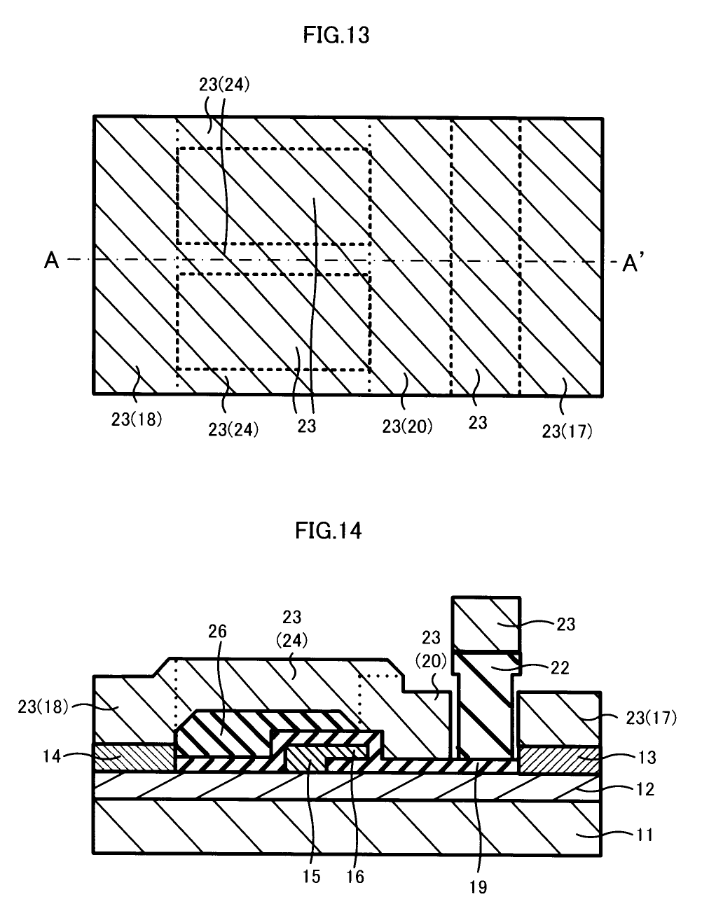

A method for manufacturing the semiconductor device shown in FIGS. 9 and 10 will be described below with reference to FIGS. 11 to 14. FIGS. 11 and 13 are top views of the device for explaining the method for manufacturing a semiconductor device according to the second embodiment. FIGS. 12 and 14 are sectional views of the device along a dotted chain line A-A′ in FIGS. 11 and 13. FIGS. 11 and 12, as in FIGS. 5 and 6, are magnified to the peripheral portion of the device for descriptive convenience.

As in the method for manufacturing a semiconductor device according to the first embodiment, more specifically, as in FIGS. 3 and 4, the drain electrode 13, the source electrode 14, the gate electrode 15, the gate field plate 16, the passivation layer 19 and the like are formed. Thereafter, as shown in FIGS. 11 and 12a second photo resist 26 is formed on a surface of the passivation layer 19 before the first photo resist 22 is formed. Thereafter, the first photo resist 22 is formed. The first photo resist 22 has the same structure as those of the first photo resist 22 shown in FIGS. 5 and 6.

The second photo resist layer 26 is a resist layer for forming a plurality of electrical connections 24 over the passivation layer 19 via a desired space 25. The second photo resist layer 26 has a width equal to the electrode widths of the source electrode 14 and the gate field plate 16. The second photo resist layer 26 is formed on the passivation layer 19 extending from an upper part of the drain-side end portion of the source electrode 14 to an upper part of the drain-side end portion of the gate field plate 16. The second photo resist layer 26, like the first photo resist layer 22, may be made by SiN layer.

The second photo resist layer 26 is manufactured by the same method as that of the first photo resist layer 22 except that a position for forming the second photo resist layer 26 is different from a position for forming the first photo resist layer 22.

As shown in FIGS. 13 and 14, the metal 23 (for example, gold) is deposited, by using the first photo resist layer 22 and the second photo resist layer 26 as masks. By the deposition of the metal, the drain connect electrode 17, the source connect electrode 18, the source field plate 20 and the plurality of electrical connections 24 which are shown in FIGS. 9 and 10 are formed at once.

Finally, the first photo resist layer 22 is removed together with the metal 23 on the layer 22. Subsequently, the second photo resist layer 26 is removed. In particular, the second photo resist layer 26 is desolved and removed by wet etching such that the second photo resist layer 26 is dipped in a chemical solution, or is removed by dry etching. In this method, the semiconductor device shown in FIGS. 9 and 10 is manufactured.

Even in the semiconductor device according to the second embodiment described above, a width of each of the electrical connections 24 is smaller than a width of a conventional electrical connection. Therefore, like the semiconductor device according to the first embodiment, the gate parasitic capacitance Cgs can be reduced, and the electric field concentration can be stably preventing along the entire width of the gate field plate 16.

Even in the semiconductor device according to the embodiment, like the semiconductor device according to the first embodiment, the number of thin electrical connections 24 is preferably small (for example, one) in terms of a reduction of the gate parasitic capacitance Cgs. However, since a stable voltage is difficult to be applied to the source field plate 20, a plurality of source field plate 20 is preferably formed.

In the semiconductor device according to the second embodiment, the plurality of electrical connections 24 are formed at an upper position spaced from the passivation layer. Therefore, the gate parasitic capacitance Cgs can be further reduced.

In the step of removing the second photo resist layer 26 in the second embodiment, the second photo resist layer 26 is exposed from portions between the pluralities of electrical connections 24. Therefore, the chemical solution to remove the second photo resist layer 26, reactive ions, an etching gas and the like penetrate from the exposed portions between the plurality of electrical connections 24 and a side surface of the second photo resist layer 26 into the entire area of the second photo resist layer 26. Therefore, the second photo resist layer 26 can be easily removed.

### Third Embodiment

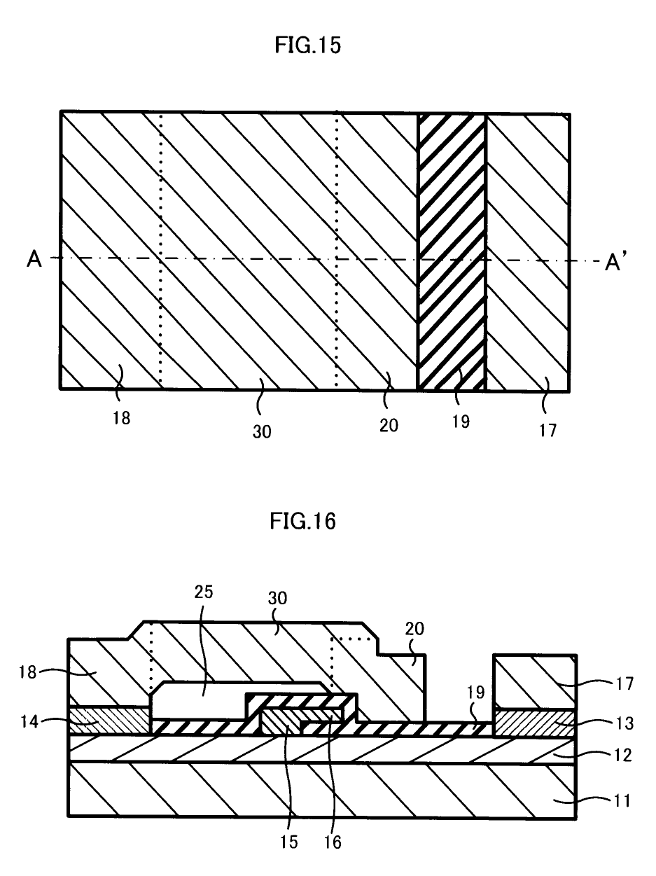

FIG. 15 is a top view showing a semiconductor device according to a third embodiment of the present invention. FIG. 16 is a sectional view of the semiconductor device along a dotted chain line A-A′ in FIG. 15. The semiconductor device shown in FIGS. 15 and 16 is different from the semiconductor device according to the second embodiment in that the source connect electrode 18 and the source field plate 20 are connected to each other by one electrical connection 30 having a electrical connection width substantially equal to the electrode widths of the electrodes 18 and 20. As in the semiconductor device according to the second embodiment, the space 25 is provided between the electrical connection 30 and the passivation layer 19.

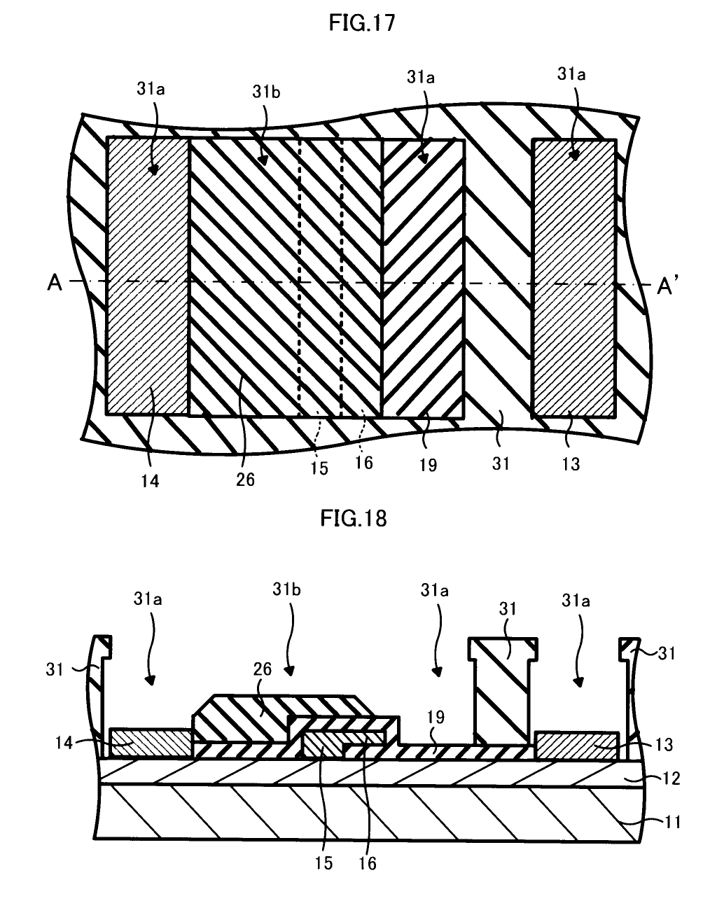

The method for manufacturing a semiconductor device will be described below with reference to FIGS. 17 and 18. FIG. 17 is a top view of the device for explaining the method for manufacturing a semiconductor device and a peripheral portion thereof, and FIG. 18 is a sectional view of the device along a dotted chain line A-A′ in FIG. 17 and a peripheral portion thereof.

The drain electrode 13, the source electrode 14, the gate electrode 15, the gate field plate 16, the passivation layer 19 and the like are formed in the same manner as that shown in FIGS. 3 and 4. Thereafter, as shown in FIGS. 17 and 18the second photo resist 26, and a first photo resist 31 is formed on a surface of the passivation layer 19. The second photo resist 26 has the same structure as the second photo resist 26 shown in FIGS. 11 and 12. The second photo resist 26 is a resist layer to form a wide electrical connection 30 on the passivation layer 19 through the desired space 25.

The first photo resist layer 31 has electrode forming openings 31a for forming the drain connect electrode 17, the source connect electrode 18 and the source field plate 20 and a electrical connection forming opening 31b for forming the electrical connection 30, as shown in FIGS. 17 and 18. Each of the openings 31a and 31b is formed in an overhung shape.

The electrode forming openings 31a are formed at least above the drain-side end portion of the gate field plate 16, the drain electrode 13 and the source electrode 14, respectively. The electrical connection forming opening 31b is formed between the electrode forming openings 31a above the source electrode 14 and the gate field plate 16 to connect the openings 31a to each other. An opening width of each of the electrical connection forming openings 31b is substantially equal to an opening width of the electrode forming opening 31a.

The first photo resist layer 31 is manufactured by the same manner as the first photo resist layer 22 shown in FIGS. 5 and 6 except that a shape of the electrical connection forming opening 31b in the first photo resist layer 31 is different from that in the photo resist layer 22.

After the first photo resist layer 31 and the second photo resist layer 26 are formed, as in the method shown in FIGS. 13 and 14, the metal 23 (for example, gold) is deposited by using the first photo resist layer 31 and the second photo resist layer 26 as masks. By depositing metal, the drain connect electrode 17, the source connect electrode 18 and the source field plate 20 are formed at once as well as the wide electrical connection 30 electrical connections 24 shown in FIGS. 15 and 16.

Finally, the first photo resist Layer 31 is removed together with the metal 23 on the layer 31. Subsequently, as in the second embodiment, the second photo resist layer 26 is removed by wet etching or dry etching. The second photo resist layer 26 can be removed although a longer time than those in the first and second embodiments is required to cause a wet etching solution or a dry etching gas to permeate in a lower side of the electrical connection 30 because the electrical connection 30 is wide. In order to shorten the time, a resist material having a high etching rate is used, or an insulating film such as SiO2 which can be easily etched may be used in place of the resist material. In this method, the semiconductor device shown in FIGS. 15 and 16 is manufactured.

In the semiconductor device according to the third embodiment described above, a width of the electrical connection 30 is substantially equal to that of a electrical connection of a conventional semiconductor device. However, the electrical connection 30 according to the third embodiment is formed at a position vertically spaced from the passivation layer. Therefore, the gate parasitic capacitance Cgs can be reduced.

While certain embodiments have been described, these embodiments have been presented by way of example only, and are not intended to limit the scope of the inventions. Indeed, the novel semiconductor device and the novel method for manufacturing a semiconductor device described herein may be embodied in a variety of other forms. Furthermore, various omissions, substitutions and changes in the form of the semiconductor device and the method for manufacturing a semiconductor device described herein may be made without departing from the spirit of the inventions. The accompanying claims and their equivalents are intended to cover such forms or modifications as would fall within the scope and spirit of the inventions.

For example, the semiconductor device according to each of the embodiments described above is a single semiconductor device. However, each of the embodiments can be similarly applied to a structure obtained by arranging and forming a plurality of semiconductor devices in parallel to each other. In this case, in particular, the electrical connections 21, 24, and 30 are formed between the source connect electrode 18 and the source field plate 20 with shortest distances. Therefore, a nonuniform operation of each of the semiconductor devices caused by small differences between the plurality of electrical connections 21, 24, and 30 is also prevented.

What is claimed is:

1. A semiconductor device comprising: an active region formed on a semiconductor substrate; a drain electrode and a source electrode formed on a surface of the active region to be separated from each other; a gate electrode formed between the drain electrode and the source electrode; a passivation layer formed on a surface of the active region between the drain electrode and the source electrode to cover the gate electrode; a source field plate electrode formed at a position including at least an upper part of a drain-side end portion of the gate electrode on a surface of the passivation layer; and an interconnection formed on the passivation layer to connected the source filed plate electrode and the source electrode and having an interconnection width smaller than an electrode widths of the electrodes.

2. The semiconductor device according to claim 1, wherein the electrical connection includes a plurality of electrical connections which are separated from each other and parallel to each other.

3. The semiconductor device according to claim 2, wherein an interval between the pluralities of electrical connections is not more than 50 μm.

4. The semiconductor device according to claim 1, further comprising a gate field plate formed on the drain-side end portion of the gate electrode, wherein the passivation layer is formed to cover the gate electrode and the gate field plate, and the source field plate is formed at least at a position including an upper part of the drain-side end portion of the gate field plate on the passivation layer.

5. The semiconductor device according to claim 1, wherein the electrical connection is formed to have a space between the electrical connection and the passivation layer.

6. The semiconductor device according to claim 5, wherein the electrical connection includes a plurality of electrical connections which are separated from each other and parallel to each other.

7. The semiconductor device according to claim 6, wherein an interval between the pluralities of electrical connections is not more than 50 μm.

8. The semiconductor device according to claim 5, further comprising a gate field plate formed on the drain-side end portion of the gate electrode, wherein the passivation layer is formed to cover the gate electrode and the gate field plate, and the source field plate is formed at a position including at least an upper portion of the drain-side end portion of the gate field plate on the passivation layer.

9. The semiconductor device according to claim 1, wherein the interconnection has an interconnection width almost equal to the electrode widths of the source filed plate electrode and the source electrode, and is formed to have a space between the interconnection and the passivation layer.

10. The semiconductor device according to claim 9, further comprising a gate field plate formed on the drain-side end portion of the gate electrode, wherein the passivation layer is formed to cover the gate electrode and the gate field plate, and the source field plate is formed at a position covering at least an upper portion of the drain-side end portion of the gate field plate on the passivation layer.

11. A method for manufacturing a semiconductor device comprising steps of: forming a drain electrode, a source electrode, and a gate electrode on a surface of a active region formed on a semiconductor substrate; forming a passivation layer on the active region between the drain electrode and the source electrode to cover the gate electrode; forming the first photo resist layer, on the passivation layer, having electrode forming openings formed at least at a position including an upper portion of the drain-side end portion of the gate electrode and on the source electrode and an interconnection forming opening formed between the electrode forming openings to connect the openings to each other and having an opening width smaller than an opening width of the electrode forming opening; depositing a metal by using the first photo resist layer as a mask; removing the first photo resist layer, and forming an interconnection electrically connected to the source field plate, the source filed plate electrode, and the source electrode and having an interconnection width smaller than electrode widths of the electrodes on the passivation layer.

12. The method for manufacturing a semiconductor device according to claim 11, wherein the electrical connection forming opening includes a plurality of electrical connection forming openings formed between the electrode forming openings, and are separated from each other and parallel to each other.

13. The method for manufacturing a semiconductor device according to claim 12, wherein an interval between the pluralities of electrical connection forming openings is not more than 50 μm.

14. The method for manufacturing a semiconductor device according to claim 11, wherein the first photo resist layer is formed on the passivation layer on the gate electrode and on the passivation layer between the source electrode and the gate electrode after a second photo resist layer is formed, and the second photo resist layer is removed after the first photo resist layer is removed.

15. The method for manufacturing a semiconductor device according to claim 14, wherein the electrical connection forming opening includes a plurality of electrical connection forming openings formed between the electrode forming openings, and are separated from each other and parallel to each other.

16. The method for manufacturing a semiconductor device according to claim 15, wherein an space between the plurality of electrical connection forming openings is not more than 50 μm.

17. The method for manufacturing a semiconductor device according to claim 11, wherein the interconnection forming opening of the first photo resist layer has an opening width equal to an opening width of the electrode forming opening, the first photo resist layer is formed on the passivation layer on the gate electrode and on the passivation layer between the source electrode and the gate electrode after a second photo resist layer is formed, and the second photo resist layer is removed after the first photo resist layer is removed.
